(19) United States
(12) Patent Application Publication
(10) Pub. No.: US 2004/0255225 A1
(43) Pub. Date: Dec. 16, 2004

(54) Control circuit for error checking and correction and memory controller

(76) Inventor: Yoriharu Takai, Ome-shi (JP)

Correspondence Address: Finnegan, Henderson, Farabow,, Garrett & Dunner, L.L.P., 1300 I Street, N.W., Washington, DC, 20005-3315, US

(21) Appl. No.: 10/765,066

(22) Filed: Jan. 28, 2004

(30) Foreign Application Priority Data
Jan. 31, 2003 (JP) 2003-024861

(51) Int. Cl. G11C 29/00

(52) U.S. Cl. 714/763

(57) ABSTRACT

A control circuit for a memory device, comprises an inverter which inverts all bits of data read out from the memory device, and a decoder which executes error correction and decoding for an output of the inverter.

### CROSS-REFERENCE TO RELATED APPLICATIONS

This application is based upon and claims the benefit of priority from the prior Japanese Patent Application No. 2003-024861, filed Jan. 31, 2003, the entire contents of which are incorporated herein by reference.

### BACKGROUND OF THE INVENTION

1. Field of the Invention

The present invention relates to a control circuit and a memory controller for error checking and correction (hereinafter referred to as ECC) in a semiconductor memory device or the like.

2. Description of the Related Art

There is a flash memory as an example of a nonvolatile semiconductor memory device. For example, in a NAND type flash memory, writing is carried out in each block of 512 bytes. In some type, the writing is executed while write address is increased continuously although the block is permitted to be discontinuous. If it is intended to write data in an intermediate block (smaller address) after it is written into discontinuous multiple blocks temporarily, it is necessary to transfer the data written in the discontinuous multiple blocks to other region and then write it into blocks whose address increases in order. At this time, data is read out from a region in which no data is written. The region in which no data is written refers to a deletion region in which data is erased. If data deletion is executed in a nonvolatile semiconductor memory device, data in the region turns to an initial value (for example, all bits are “1”).

On the other hand, data to be written into the nonvolatile semiconductor memory device is subjected to error correction and coding processing, so that ECC bit data (1 bit or several bits) is added to proper write data. Data read out from the nonvolatile semiconductor memory device is subjected to error correction and decoding. Although data in the deletion region is, for example, constructed so that its bit string is all “1,” ordinary ECC data, for example, an extended hamming code data does not have a case that the ECC data is not all “1,” nor all “0” when the bit string is all “1,” or all “0.” Thus, although data read out from the deletion region has no error (data is correct), it is determined that there is an ECC error.

To prevent erroneous determination about ECC error, the ECC control circuit includes two inverters for encoder and decoder. By inverting an output of the ECC encoder and an output of the ECC decoder appropriately, the erroneous detection of the ECC error is prevented (see Japanese Patent KOKAI Publication No. 2001-92723, paragraphs [0013] and [0014], FIG. 3)

The ECC control circuit described in this document comprises a check bit generating circuit, a syndrome decoder (ECC decoder), a first bit inverter for inverting at least part of check bit data generated from the check bit generating circuit, and a second bit inverter for inverting at least part of check bit data read out from a nonvolatile memory for storing the check bit data.

The first bit inverter inverts a bit or bits of the check bit data generated with regard to an initial value in a data region so as to be equal to an initial value after erasure. The second bit inverter inverts a bit or bits of the check bit data read out from the nonvolatile memory for storing check bit data in the same bit or bits as the first bit inverter.

Upon writing data, data is written into the nonvolatile memory for storing data and supplied to the check bit generating circuit. The check bit generating circuit generates check bit data corresponding to write data. The first bit inverter inverts an appropriate bit or bits of the check bit data so as not to produce any ECC error and writes the inverted check bit data into the nonvolatile memory for storing check bit data.

Upon reading data, data is read out from the nonvolatile memory for storing data and supplied to the ECC control circuit. Check bit data is read out from the nonvolatile memory for storing check bit data and while part thereof is inverted, supplied to the syndrome decoder through the second bit inverter. The syndrome decoder appropriately corrects the inverted check bit data if there is any error and after the correction, sends the corrected data to a data bus.

In this way, erroneous detection of the ECC error is prevented by generating the check bit data from data read out from the deletion region and appropriately inverting part thereof so as not to generate an error.

However, because this document does not consider the property of the ECC code, the inverter becomes complicated as bit to be inverted by the bit inverter is not fixed. Generally, the integrated circuit needs a simulation test after its circuit is described. However, a complicated inverter has a number of test items and takes a long time to make a test.

### BRIEF SUMMARY OF THE INVENTION

The present invention is directed to a control circuit and a memory controller that substantially obviate one or more of the problems due to limitations and disadvantages of the related art.

According to an embodiment of the present invention, a control circuit for a memory device, comprising:

an inverter which inverts all bits of data read out from the memory device; and

a decoder which executes error correction and decoding for an output of the inverter.

According to another embodiment of the present invention, a control circuit for a memory device, comprising:

a first inverter which inverts all bits of data to be written into the memory device;

an encoder which executes error correction and coding for an output of the first inverter;

a second inverter which inverts all bits of data to be output from the encoder and writes the inverted data into the memory device;

a third inverter which inverts all bits of data read out from the memory device; and

a decoder which executes error correction and decoding for an output of the third inverter.

According to another embodiment of the present invention, a memory controller for a memory device, comprising:

a buffer which holds data temporarily;

a first inverter which inverts all bits of data to be written from the buffer into the memory device;

an encoder which executes error correction and coding for an output of the first inverter;

a second inverter which inverts all bits of data to be outputted from the encoder and writes the inverted data into the memory device;

a third inverter which inverts all bits of data read out from the memory device; and

a decoder which executes error correction and decoding for an output of the third inverter.

Additional objects and advantages of the present invention will be set forth in the description which follows, and in part will be obvious from the description, or may be learned by practice of the present invention.

The objects and advantages of the present invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the present invention and, together with the general description given above and the detailed description of the embodiments given below, serve to explain the principles of the present invention in which:

FIG. 1 is a diagram showing an outline of a Reed-Solomon coding system;

FIG. 2 is a block diagram showing a configuration of a first embodiment of an ECC control circuit according to the present invention;

FIG. 3 is a flow chart showing a data writing processing;

FIG. 4 is a flow chart showing a data reading processing;

FIG. 5 is a block diagram showing a configuration of a second embodiment of an ECC control circuit according to the present invention;

FIG. 6 is a flow chart showing an operation test to be applied to the ECC control circuit according to the first and second embodiments of the present invention; and

FIG. 7 is a flow chart showing the detail of functional simulation of the flow chart shown in FIG. 6.

### DETAILED DESCRIPTION OF THE INVENTION

An embodiment of an ECC control circuit according to the present invention will now be described with reference to the accompanying drawings. For convenience for description, it is assumed that a nonvolatile semiconductor memory device is a flash memory and a bit string of an initial value after erasure is all “1” while an error correction code is a Reed-Solomon code.

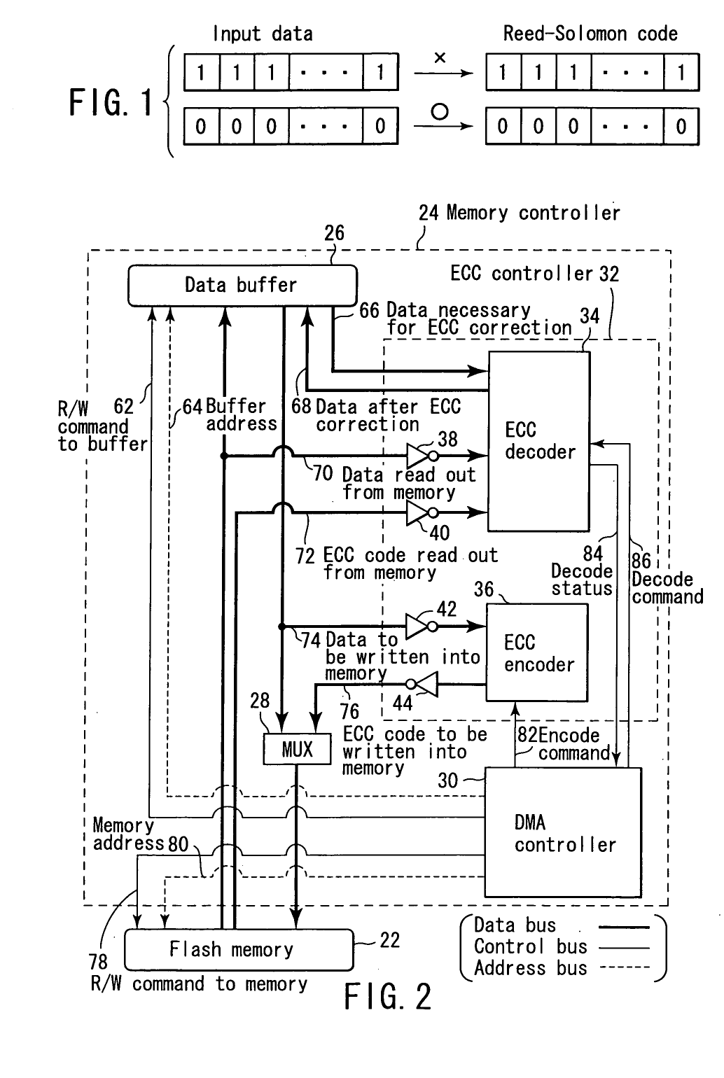

FIG. 1 shows the relation between input data for a Reed-Solomon coding circuit and an output code therefrom. Because the Reed-Solomon code is formed of a combination of EX-ORs of input data bits, if the input data is all “0,” the Reed-Solomon code is also all “0.” However, if the input data is all “1,” the Reed-Solomon code is not all “1” in most cases. For the reason, if the initial value after erasure is all “1,” it means that both input data and code are all “1” and thus, it is determined that an ECC error exists.

### FIRST EMBODIMENT

FIG. 2 is a diagram showing the entire configuration of a system including an ECC circuit according to a first embodiment of the present invention. According to this embodiment, an inverter is connected to a data bus and an ECC code bus such that any ECC error is not detected from the initial value after erasure.

A memory controller 24 is connected to a flash memory 22 through a data bus, a control bus and an address bus. The memory controller 24 comprises a data buffer 26, a multiplexer 28, a DMA controller 30, and an ECC controller 32. The data buffer 26 temporarily holds write data to be written into the flash memory 22 and read data to be read out from the flash memory 22. The ECC controller 32 executes ECC coding processing for the write data and ECC decoding processing for the read data. The multiplexer 28 selectively supplies data from the data buffer 26 and data from the ECC controller 32 to the flash memory 22. The DMA controller 30 supplies address data and control data to the flash memory 22 and the data buffer 26 and supplies a command to the ECC decoder 34 and ECC encoder 36.

The ECC controller 32 comprises the ECC encoder 36, the ECC decoder 34, and inverters 38, 40, 42 and 44. The ECC encoder 36 generates an ECC code based on data supplied from the data buffer 26. The ECC decoder 34 determines whether or not there is a data error based on data read out from the flash memory 22 and the ECC code and if the error is detected and can be corrected, corrects it. The inverter 38 inverts all bits of data to be supplied to the ECC decoder 34 (data read out from the flash memory 22). The inverter 40 inverts all bits of the ECC code (ECC code read out from the flash memory 22) to be supplied to the ECC decoder 34. The inverter 42 inverts all bits of data (data to be written into the flash memory 22) to be supplied to the ECC encoder 36. The inverter 44 inverts all bits of the ECC code output from the ECC encoder 36.

The operation of the system having the above-described configuration will be described below.

<Data Write>

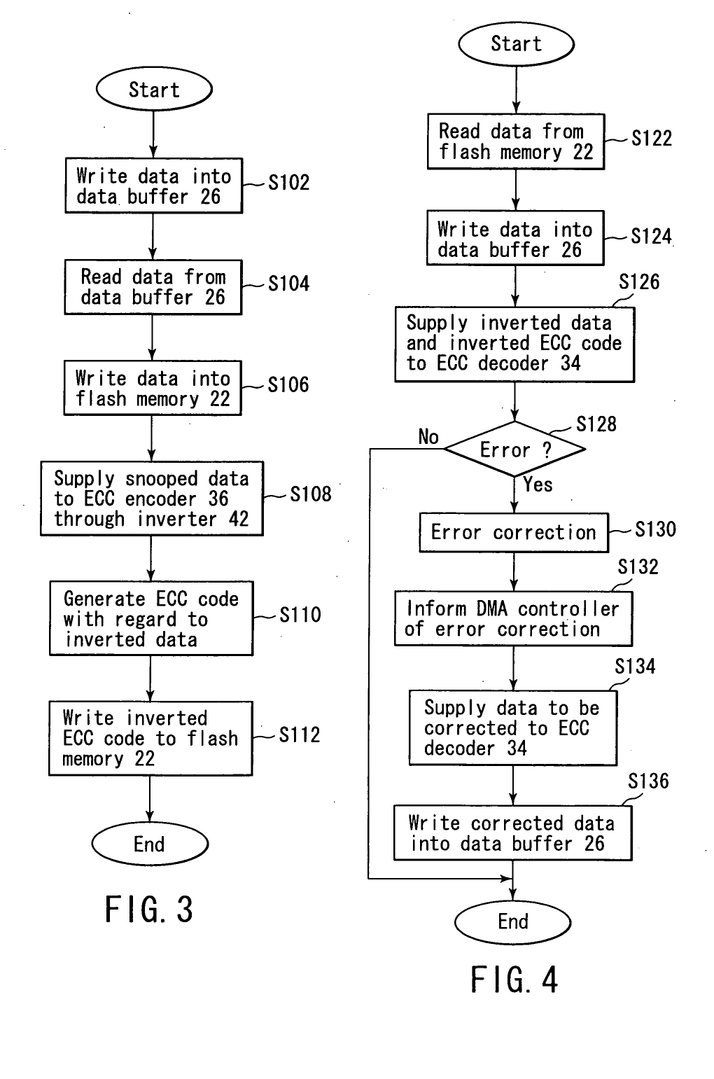

The write processing will be described with reference to the flow chart of FIG. 3. In step S102, data to be written into the flash memory 22 is written into the data buffer 26 temporarily. In step S104, the DMA controller 30 issues a read command through a data buffer command line 62 and a desired address through a data buffer address line 64 to the data buffer 26, thereby reading data (data to be written into the flash memory 22) from the data buffer 26.

In step S106, the DMA controller 30 issues a write command through a flash memory command line 78 and a desired address through a flash memory address line 80 to the flash memory 22, thereby writing data into the flash memory 22 through the multiplexer 28.

In step S108, the DMA controller 30 sends an encoding start command to the ECC encoder 36 through an encode command line 82 to invert data snooped from a data bus between the data buffer 26 and the flash memory 22 by means of the inverter 42 and send the inverted data to the ECC encoder 36.

When data is being transferred from the data buffer 26 to the flash memory 22 in step S110, the multiplexer 28 causes data to pass. After data transfer through a flash memory input data bus which is an output of the multiplexer 28 is finished, the ECC encoder 36 generates an ECC code for an inverted value of data read out from the data buffer 26.

In step S112, the ECC code output from the ECC encoder 36 is inverted through the inverter 44 and an inverted value of this ECC code is written into the flash memory 22 through the multiplexer 28.

If data of all “1” is written into the flash memory 22 following the above-described procedure, data to be input into the ECC encoder 36 is inverted to all “0.” Consequently, an ECC code of all “0” is generated in the ECC encoder 36. Because this ECC code is inverted and written into the flash memory 22, both of write data and ECC code of all “1” are written into the flash memory 22.

<Data Read>

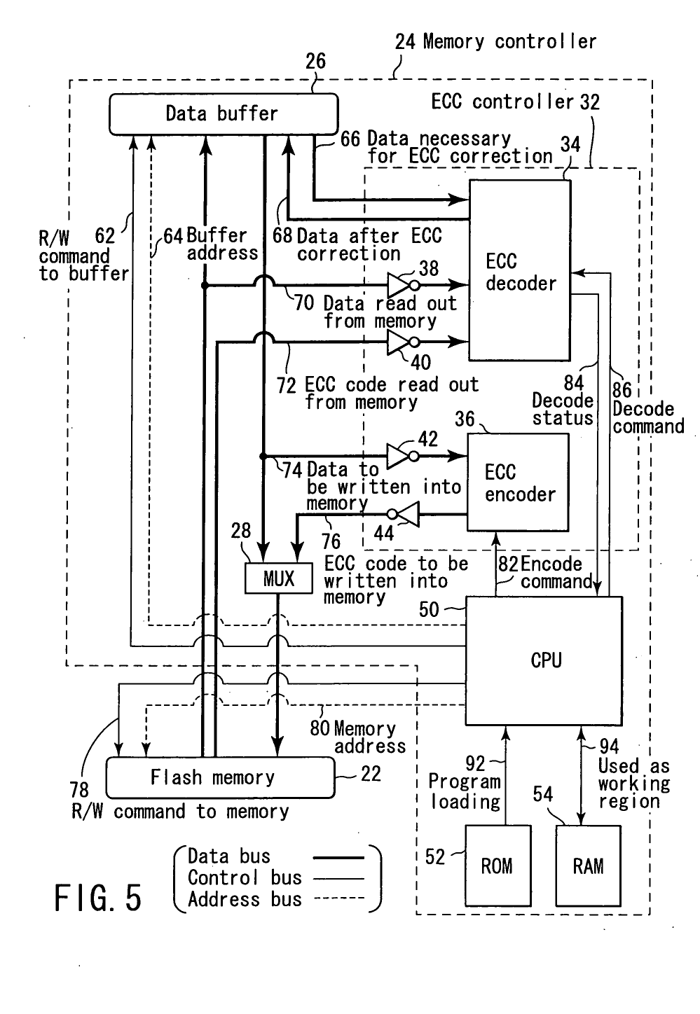

The data read processing will be described with reference to the flow chart of FIG. 4. When the DMA controller 30 issues a read instruction through the flash memory command line 78 and a desired address through the flash memory address line 80 to the flash memory 22 in step S122, data is read from the flash memory 22.

When the DMA controller 30 issues a write command through the data buffer command line 62 and a desired address through the data buffer address line 64 to the data buffer 26 in step S124, data read out from the flash memory 22 is written into the data buffer 26 through the data bus between the flash memory 22 and the data buffer 26.

In step S126, the DMA controller 30 sends a decoding start command to the ECC decoder 34 through a decode command line 86. Then, an inverted value of read data is sent from an ECC decoder input data inversion bus, which is an output of the inverter 38 to the ECC decoder 34 and an inverted value of the ECC code is sent from an ECC data input ECC code inversion bus, which is an output of the inverter 40, to the ECC decoder 34.

If there is an error in data as a result of decoding by the ECC decoder 34 and whether or not that data error needs to be corrected is determined in step S128. If the correction is necessary, data correction operation is started in step S130. While the ECC decoder 34 specifies and corrects a correction object, a decode status line 84 is made busy and it is notified to the DMA controller 30 that the correction object is being specified and corrected and then read/write operation to the data buffer 26 is prohibited in step S132.

In step S134, the ECC decoder 34 reads information about the correction object from the data buffer 26 through an ECC correction read data bus 66. In step S136, the ECC decoder 34 corrects error data at a bit position to be corrected by bit inversion and writes the corrected data into the data buffer 26 through an ECC correction write data bus 68.

When data of all “1” is read out from the flash memory 22 following the above-described procedure, data to be input to the ECC decoder 34 is inverted by the inverter 38 so that it turns to all “0.” Further, because the ECC code is also inverted by the inverter 40 and turned to all “0,” an erroneous detection of the ECC error as shown in FIG. 1 never occurs.

As described above, according to this embodiment, if data is written into the flash memory 22, “an inverted value of a reed-Solomon code calculated from the inverted value of data” is written into the flash memory 22 as an ECC code. That is, if bits in data region are all “1,” the ECC code of all “1” is written. When an initial value (all “1”) after erasure is read out from the flash memory 22, data to be input to the ECC decoder 34 is all “0” and the ECC code is also all “0.” Thus, no ECC error is detected.

If the ECC determination is carried out as usually after the memory is erased, an error is detected by mistake. According to the prior art document, the ECC code is generated from data after the memory is erased and this code data is inverted appropriately so as not to produce an error. Contrary to this, according to this embodiment, after all bits of data are inverted after the memory is erased, this data is input to the ECC control circuit to generate an ECC code. Although according to the prior art document, a single unit test for the ECC encoder/decoder is hard to execute because an inverter is included in the ECC encoder/decoder, according to this embodiment, the single unit test for the ECC encoder/decoder is easy because the inverter is connected outside the existing ECC encoder/decoder.

Other embodiments of the ECC control circuit according to the present invention will be described. The same portions as those of the first embodiment will be indicated in the same reference numerals and their detailed description will be omitted.

### SECOND EMBODIMENT

Although according to the first embodiment shown in FIG. 2, the ECC control is performed by the DMA controller 30, that control can be carried out by using a CPU instead of the DMA controller 30 also. FIG. 5 is a block diagram of the second embodiment which achieves this. That is, a CPU 50 is provided instead of the DMA controller 30. A ROM module 52 which stores a program for actuating the CPU 50 and a RAM module 54 serving as a working region for the CPU 50 are provided. Following two controls are different as compared to a case where the DMA controller 30 carries out the ECC control.

(1) Before carrying out the ECC control, the CPU 50 loads a program from the ROM module 52 through a program read data line 92.

(2) When the ECC control is carried out, the CPU 50 uses the RAM module 54 as a working region through a RAM access data line 94.

The other control is the same as the first embodiment.

As described above, the second embodiment can provide the same effect as the first embodiment also.

Next, an LSI test for use in the first and second embodiments having the above-descried configuration will be described.

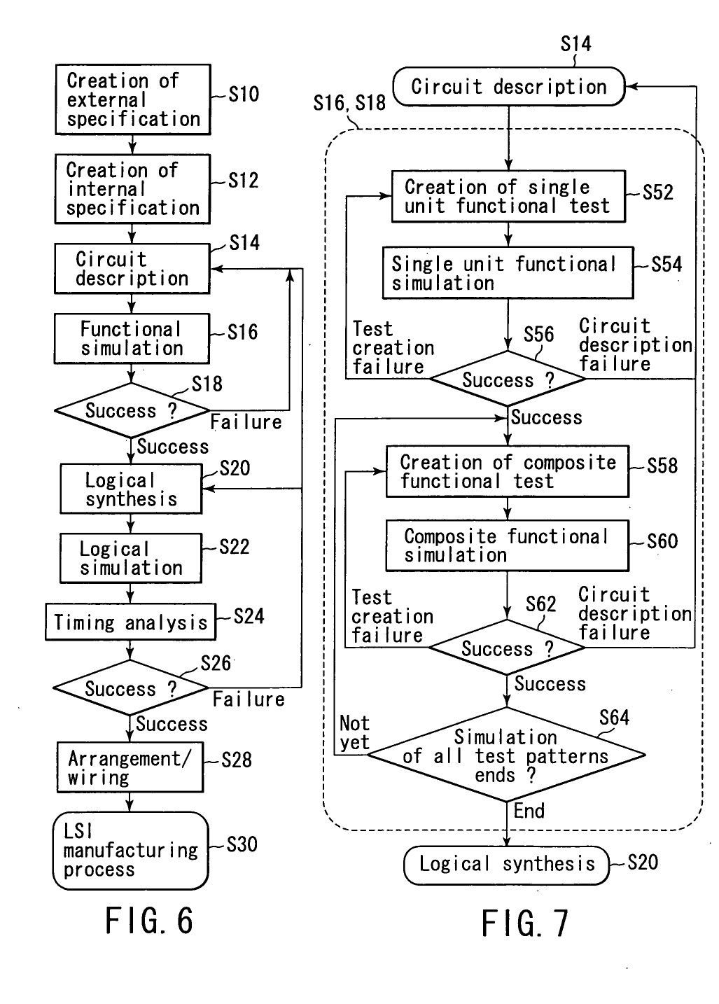

FIG. 6 shows a general LSI design flow. In step S10, LSI external specifications including chip, package, cost, frequency, circuit scale estimation and the like are determined. In step S12, a function in charge of each module within the LSI (internal specification) is determined in accordance with the external specification. In step S14, a circuit is described using hardware descriptive language according to the internal specification. In step S16, whether or not the function of the described circuit is activated properly is verified (functional simulation). In step S18, whether or not the simulation is successful (the circuit function is activated properly) is determined.

In the case of failure, the processing returns to the description of the circuit (step S14). In the case of success, in step S20, the circuit described with the hardware descriptive language is converted to a logical gate such as AND gate and OR gate (logical synthesis). The circuit converted to the logical gate is called “net.”

In step S22, it is verified whether or not the “net” has a similar function to the circuit described with the hardware descriptive language (logical simulation). The verification contents are often similar to a verification test on the functional simulation. In step S24, it is verified whether or not the “net” is operated properly under a desired operation frequency (timing analysis). Because step S22 and step S24 can be executed in parallel, any one of them may be executed in advance. In step S26, it is determined whether or not the logical simulation and timing analysis succeed (the “net” is operated properly).

If the functional simulation is operated normally or the timing analysis does not succeed, the circuit description is changed and the functional simulation is retried (return to step S14). If an abnormality is found in the “net” by the logical simulation or the timing analysis, the logical synthesis is retried (return to step S20) or the processing is retried from the description of the circuit (return to step S14). In case of success, in step S28, the logical gate is disposed and wired on an actual LSI substrate.

FIG. 7 shows the detail of the functional simulation (steps S16 and S18) of FIG. 6. The single unit function mentioned in the same figure refers to the function of a single module such as the ECC decoder 34, the ECC encoder 36 and the DMA controller 30. Contrary to this, the composite function refers to functions by combination of multiple functions such as the ECC decoder 34 with the inverters 38 and 40, the ECC encoder 36 with the inverters 42 and 44, the ECC decoder 34 with the ECC encoder 36 and the inverters 38, 40, 42 and 44. In most cases, the composite function is more complicated than the single unit function and therefore, a test for verifying the function varies in many ways, so that creation and verification method for a test pattern are likely to be difficult. For the reason, to verify the circuit described with hardware language, generally the composite function test is not carried out until it is verified that the function of the single unit is right by first carrying out the single function test as shown in FIG. 5.

If taking the ECC decoder 34 as an example, to verify the function of the ECC decoder 34, a test pattern for its single unit function is created in step S52. In step S54, the single unit function is simulated. In step S56, it is determined whether or not the simulation succeeds and if it fails, which its cause originates from the test pattern or the circuit description. Then, the processing returns to a step which falls under the cause, which needs be retried.

In step S58, a test pattern for a test on the composite function (for example, function in which the ECC decoder and inverter are combined) is created. In step S60, a simulation for the composite function is carried out. In step S62, whether or not the simulation succeeds and if it fails, which its cause originates from the test pattern or circuit description are determined and then, the processing returns to a step which falls under the cause, which needs to be retried. As for the composite function test, its test patterns exist by the same number as the number of combinations of the functions of each module, different from the single unit function test. If the number of the test patterns is large, it takes longer correspondingly to take a test and the test simulation time is increased. Therefore, LSI development is actually difficult.

Because the inverter which inverts data and ECC code of this embodiment described above, automatically inverts all bits using the property of the Reed-Solomon code, only a single pattern is available as the test pattern for functional simulation. However, because according to the inverter mentioned in the prior art document, the check bit data needs to be inverted appropriately corresponding to the property of the data flash memory or check bit data flash memory, the test patterns are required by 2 to the power of the check bit data. For the reason, the creation of the composite function test patterns and the composite function simulation needs to be executed times of 2 to the power of the check bit data and it is very difficult to execute the functional simulation for all the test patterns. It is difficult to execute the logical simulation also because the logical simulation uses this test pattern.

According to the embodiments of the present invention, there are provided a control circuit and a memory controller which never execute erroneous detection on the ECC error with regard to an initial value after erasure and carry out an operation test easily.

While the description above refers to particular embodiments of the present invention, it will be understood that many modifications may be made without departing from the spirit thereof. The accompanying claims are intended to cover such modifications as would fall within the true scope and spirit of the present invention. The presently disclosed embodiments are therefore to be considered in all respects as illustrative and not restrictive, the scope of the invention being indicated by the appended claims, rather than the foregoing description, and all changes that come within the meaning and range of equivalency of the claims are therefore intended to be embraced therein.

For example, although the Reed-Solomon code has been described as the ECC code in the above description, another ECC code may be used. For example, the present invention can be applied to such an ECC coding system in which the ECC error occurs if the ECC bit is always all “0” when bit string is all “1” and such a memory in which the bit string turns to all “0” after erasure. Further, although the initial value after the memory is erased is all “1,” the present invention is not restricted to this example.

For example, the present invention can be practiced as a computer readable recording medium in which a program for allowing the computer to function as predetermined means, allowing the computer to realize a predetermined function, or allowing the computer to conduct predetermined means.

What is claimed is:

1. A control circuit for a memory device, comprising:
an inverter which inverts all bits of data read out from the memory device; and
a decoder which executes error correction and decoding for an output of the inverter.

2. The control circuit according to claim 1, wherein the decoder detects that there is no error for an inverted value of all bits of an initial value after data in the memory device is erased.

3. The control circuit according to claim 1, wherein the memory device comprises a nonvolatile semiconductor memory device.

4. A control circuit for a memory device, comprising:
a first inverter which inverts all bits of data to be written into the memory device;
an encoder which executes error correction and coding for an output of the first inverter;
a second inverter which inverts all bits of data to be output from the encoder and writes the inverted data into the memory device;
a third inverter which inverts all bits of data read out from the memory device; and
a decoder which executes error correction and decoding for an output of the third inverter.

5. The control circuit according to claim 4, wherein a coding method of the encoder is a method in which the decoder detects that there is no error for an inverted value of all bits of an initial value after data in the memory device is erased.

6. The control circuit according to claim 4, wherein the decoder detects that there is no error for an inverted value of all bits of an initial value after data in the memory device is erased.

7. The control circuit according to claim 4, wherein the memory device comprises a nonvolatile semiconductor memory device.

8. A memory controller for a memory device, comprising:
a buffer which holds data temporarily;
a first inverter which inverts all bits of data to be written from the buffer into the memory device;
an encoder which executes error correction and coding for an output of the first inverter;
a second inverter which inverts all bits of data to be outputted from the encoder and writes the inverted data into the memory device;
a third inverter which inverts all bits of data read out from the memory device; and
a decoder which executes error correction and decoding for an output of the third inverter.

9. The memory controller according to claim 8, wherein a coding method of the encoder is a method in which the decoder detects that there is no error for an inverted value of all bits of an initial value after data in the memory device is erased.

10. The memory controller according to claim 8, wherein the decoder detects that there is no error for an inverted value of all bits of an initial value after data in the memory device is erased.

11. The memory controller according to claim 8, further comprising a selector which selectively supplies an output of the buffer and an output of the encoder to the memory device.

12. The memory controller according to claim 8, wherein the memory device comprises a nonvolatile semiconductor memory device.
